(19) United States
(12) Patent Application Publication
(10) Pub. No.: US 2026/0011982 A1
(43) Pub. Date: Jan. 8, 2026

(54) METHOD OF FABRICATING SEMICONDUCTOR OPTICAL DEVICE

(71) Applicant: Source Photonics Taiwan, Inc., HSINCHU (TW)

(72) Inventors: HORNG-SHYANG CHEN, HSINCHU COUNTY (TW); HAO-HSIANG TANG, HSINCHU COUNTY (TW); HSUYING CHEN, HSINCHU CITY (TW); THANT ZIN, HSINCHU CITY (TW); NI YEH WU, HSINCHU CITY (TW)

(21) Appl. No.: 18/765,264

(22) Filed: Jul. 7, 2024

(51) Int. Cl. H01S 5/227; H01S 5/22

(52) U.S. Cl. CPC H01S 5/2275; H01S 5/2222

(57) ABSTRACT

A method of fabricating a semiconductor optical device is provided. The method includes steps of: providing a semiconductor substrate having a first conductivity type; depositing a first cladding layer having the first conductivity type on the semiconductor substrate; depositing an active layer on the first cladding layer; depositing a second cladding layer having a second conductivity type on the active layer, wherein the second conductivity type is different from the first conductivity type; forming a patterned mask layer over the second cladding layer; and performing an etching operation to sequentially remove portions of the second cladding layer, the active layer and the first cladding layer exposed through the patterned mask layer, thereby forming a mesa structure on the semiconductor substrate, wherein the etching operation uses an etchant comprising Br-based chemicals.

### TECHNICAL FIELD

The present disclosure relates to a method of manufacturing a semiconductor optical device, and more particularly, to a method of manufacturing a buried hetero-structure semiconductor laser.

### BACKGROUND

Buried hetero-structure semiconductor lasers have become widely used in recent years as laser sources for, for example, optical communication systems. In a conventional buried hetero-structure semiconductor laser, an active layer of a semiconductor material (i.e., the layer in which photons constituting the laser are actually generated) is buried within a semiconductor material having a larger bandgap. Semiconductor layers surrounding the active layer are grown to create a reverse biased junction, wherein the active layer is positioned in a gap in the reverse biased junction. During operation of a device, electrical current flows across the semiconductor layers, in a direction substantially perpendicularly to the semiconductor layers. The reverse biased junction provides resistance to such electrical current, and the flow of current is directed through the gap in the reverse-biased junction, and hence through the active layer.

### SUMMARY

One aspect of the present disclosure provides a method of fabricating a semiconductor optical device. The method includes steps of providing a semiconductor substrate having a first conductivity type; depositing an active layer over the semiconductor substrate; depositing a first cladding layer having a second conductivity type on the active layer, wherein the second conductivity type is different from the first conductivity type; forming a patterned mask layer over the first cladding layer; and performing a first etching operation to remove portions of the first cladding layer and the active layer exposed through the patterned mask layer, thereby forming a mesa structure on the semiconductor substrate, wherein the first etching operation uses an etchant comprising Br-based chemicals.

In some embodiments, the etchant comprises bromide (Br) and hydrogen bromide (HBr).

In some embodiments, the first etching operation is performed using bromide (Br) and hydrogen bromide (HBr) in a ratio of about 1:17.

In some embodiments, the etchant comprises about 30 ml of a mixture of bromide (Br) and hydrogen bromide (HBr), and about 80 ml of water.

In some embodiments, the first etching operation is performed for a duration of about 70 seconds.

In some embodiments, the method further includes steps of depositing a first current-blocking layer having the second conductivity type around the mesa structure; depositing a second current-blocking layer having the first conductivity type on the first current-blocking layer; depositing a third current-blocking layer having the second conductivity type on the second current-blocking layer; removing the patterned mask layer from the first cladding layer; and depositing a capping layer having the second conductivity type over the mesa structure and the third current-blocking layer.

In some embodiments, a width of the mesa structure tapers from the semiconductor substrate toward the first cladding layer.

In some embodiments, the mesa structure comprises an inclined surface having a substantially consistent inclination along the entire inclined surface.

In some embodiments, the mesa structure comprises a curved surface having a substantially consistent curvature along the entire curved surface.

In some embodiments, the forming of the patterned mask layer includes steps of depositing an insulating layer on the first cladding layer; forming a photoresist pattern on the insulating layer; and performing a dry etching operation on portions of the insulating layer exposed through the photoresist pattern.

In some embodiments, the insulating layer has a thickness between about 2500 angstroms and about 3500 angstroms.

In some embodiments, the method further includes a step of depositing a second cladding layer on the semiconductor substrate before the deposition of the active layer, wherein a portion of the second cladding layer not protected by the patterned mask layer is etched during the first etching operation.

In some embodiments, the semiconductor substrate, the first cladding layer, and the second cladding layer comprise indium phosphide (InP).

In some embodiments, a width of the mesa structure deviates from a predetermined width by substantially less than 0.1 μm, and a height of the mesa structure deviates from a predetermined height by less than 0.1 μm.

One aspect of the present disclosure provides a method of fabricating a semiconductor optical device. The method includes a step of loading a layer stack into an etching chamber, wherein the layer stack includes a semiconductor substrate having a first conductivity type; an active layer over the semiconductor substrate; a first cladding layer having a second conductivity type on the active layer, wherein the second conductivity type is different from the first conductivity type; and a patterned mask layer on the first cladding layer. The method further includes a step of supplying an etchant into the etching chamber to remove portions of the first cladding layer and the active layer exposed by the patterned mask layer to form an opening having a sidewall, wherein the entire sidewall has a substantially consistent gradient, and the etchant comprises Br-based chemicals.

In some embodiments, the sidewall forms a curve with increasing curvature from the semiconductor substrate toward the first cladding layer.

In some embodiments, the opening is formed by a wet etching operation.

In some embodiments, the wet etching operation is performed using the etchant, wherein the etchant comprises bromide (Br) and hydrogen bromide (HBr).

In some embodiments, the wet etching operation is performed using bromide (Br) and hydrogen bromide (HBr) in a ratio of about 1:17.

In some embodiments, the wet etching operation is performed using the etchant, wherein the etchant comprises about 30 ml of a mixture of bromide (Br) and hydrogen bromide (HBr), and about 80 ml of water.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a flow diagram illustrating a method of fabricating a semiconductor optical device in accordance with some embodiments of the present disclosure.

FIGS. 2 to 5 illustrate cross-sectional views of intermediate stages in formation of a semiconductor optical device in accordance with some embodiments of the present disclosure.

FIG. 6 illustrates a top view of an intermediate stage in the formation of the semiconductor optical device in accordance with some embodiments of the present disclosure.

FIGS. 7 to 12 illustrate cross-sectional views of intermediate stages in the formation of the semiconductor optical device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence, order, or importance unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range (e.g., within 10%, 5%, 1%, or 0.5% of a given value or range) that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

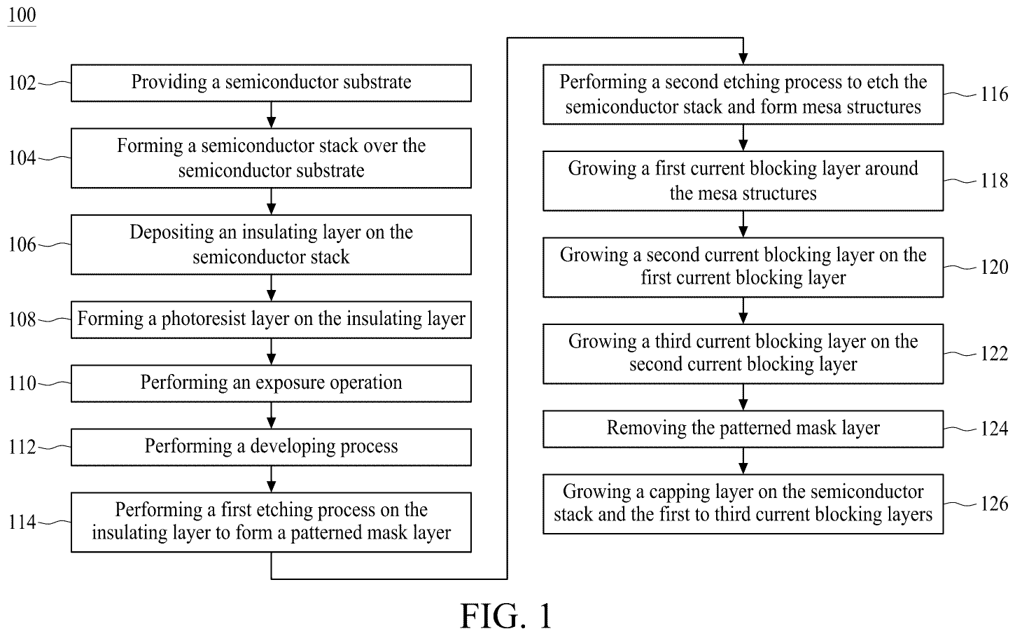

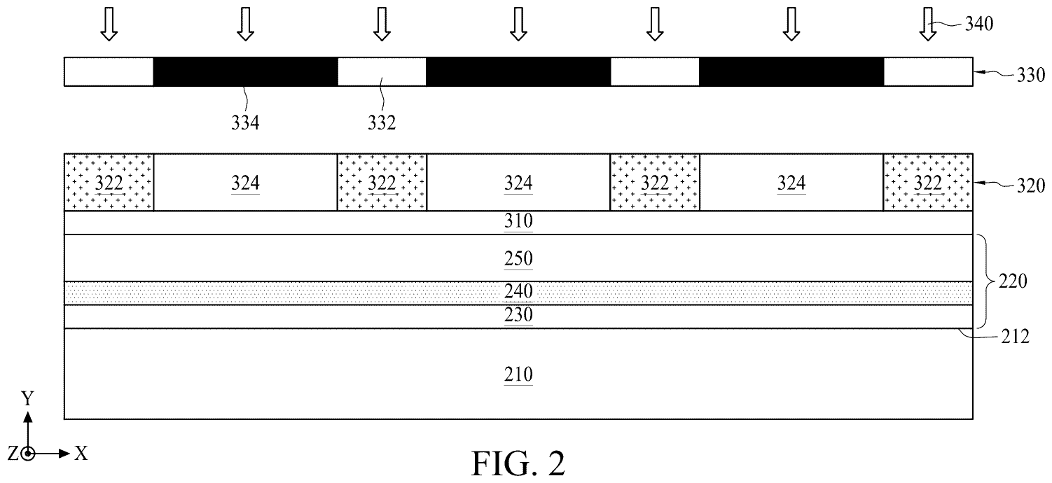

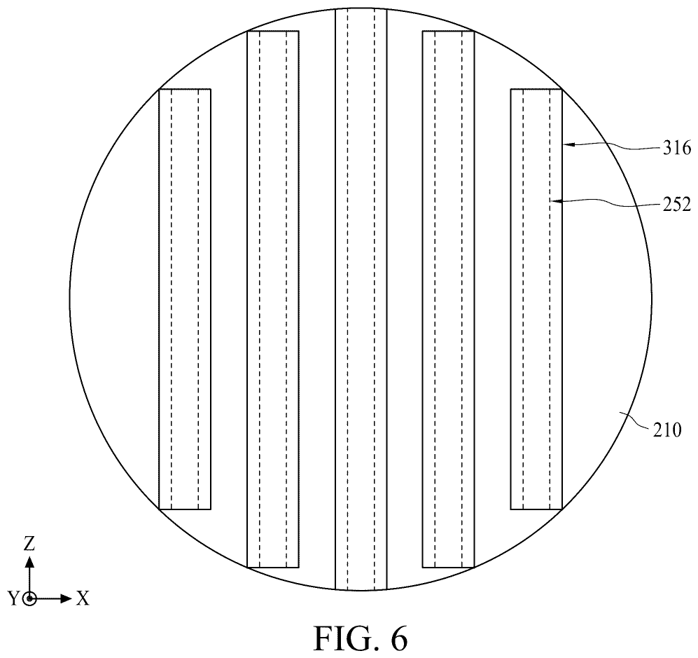

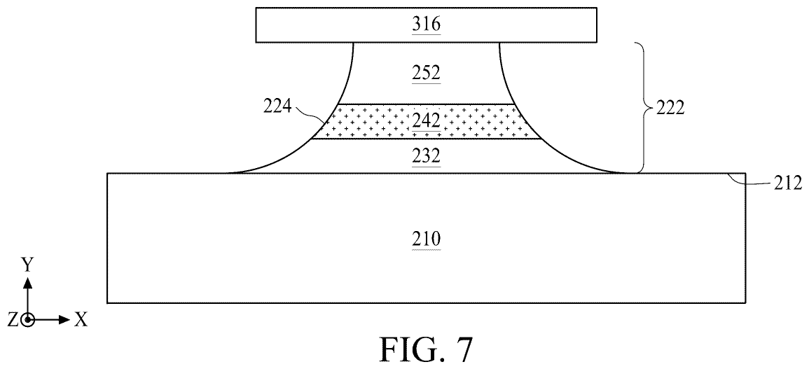

FIG. 1 is a flowchart of a method 100 of manufacturing a semiconductor optical device 20, in accordance with some embodiments of the present disclosure. FIGS. 2 to 5 are cross-sectional views of intermediate stages of the method 100 of manufacturing the semiconductor optical device 20, in accordance with some embodiments of the present disclosure. FIG. 6 is a top view of an intermediate stage of the method 100 of manufacturing the semiconductor optical device 20, and FIGS. 7 to 12 are cross-sectional views of intermediate stages of the method 100 of manufacturing the semiconductor optical device 20, in accordance with some embodiments of the present disclosure. In the following discussion, the manufacture stages illustrated in FIGS. 2 to 12 are discussed in reference to the process steps shown in FIG. 1. It should be understood that additional steps can be provided before, during, and after the steps shown in FIG. 1, and that some of the steps described below can be replaced or eliminated for additional embodiments of the method 100. The order of the steps may be changed.

In some embodiments, the method 100 fabricates a buried hetero-structure (BH) laser diode (LD). Referring to FIGS. 1 and 2, the method 100 begins at step 102, in which a semiconductor substrate 210 is provided. The semiconductor substrate 210 may be of a first conductivity type. In some embodiments, the semiconductor substrate 210 is made of an InP-based Group III-V compound semiconductor.

The InP-based Group III-V compound semiconductor includes InP and a Group III-V compound semiconductor which is perfectly or approximately lattice-matched to InP. The InP-based Group III-V compound semiconductor further includes a Group III-V compound semiconductor which is pseudomorphic to InP. The term “pseudomorphic” usually refers to a semiconductor layer that has a crystal structure in which a lattice constant in a laminate in-plane direction is equal to a lattice constant in a laminate in-plane direction of InP, and in which the lattice constant in a laminating direction is different from the lattice constant in a laminating direction of InP. However, in some embodiments, “pseudomorphic” includes not only an ideal state in which a lattice mismatch is not present but also a state in which a minor lattice defect (which is described below) not adversely affecting device characteristics is present. Examples of the Group III-V compound semiconductor which is pseudomorphic to InP and is used in the semiconductor substrate 210 include InGaAs, InGaAlAs, InGaAsP, InGaAlAsP, and the like.

Still referring to FIG. 2, a semiconductor stack 220 is formed over the semiconductor substrate 210 according to step 104 in FIG. 1. The semiconductor stack 220 includes an active layer 240 formed over a front surface 212 of the semiconductor substrate 210. The active layer 240 is capable of generating electromagnetic radiation and gain for lasing. The active layer 240 may be a bulked layer, a single quantum well structure, or a multi-quantum well structure.

The semiconductor stack 220 further includes a first cladding layer 230 and a second cladding layer 250 disposed on opposite sides of the active layer 240. The first and second cladding layers 230 and 250 confine carriers within the active layer 240. As shown in FIG. 2, the first cladding layer 230 is in contact with the front surface 212 of the semiconductor substrate 210, and the active layer 240 and the second cladding layer 250 are sequentially disposed on the first cladding layer 230.

The first cladding layer 230 has the first conductivity type, and the second cladding layer 250 has a second conductivity type different from the first conductivity type. For example, the first conductivity type is P-type, and the second conductivity type is N-type, or vice versa. The first and second cladding layers 230 and 250 are formed of a III-V group compound semiconductor, for example, InP. The first cladding layer 230 may be an optional layer that can be omitted in some embodiments. In such embodiments, the semiconductor substrate 210 functions as the first cladding layer 230. By omitting the first cladding layer 230, a duration of a manufacturing process is reduced.

The first cladding layer 230, the active layer 240, and the second cladding layer 250 are grown sequentially on the front surface 212 of the semiconductor substrate 210 by an epitaxial growth operation. Examples of the epitaxial growth operation include metal organic chemical vapor deposition (MOCVD), metal organic vapor phase epitaxy (MOVPE), and other applicable processes.

After the semiconductor stack 220 is formed, an insulating layer 310 is deposited on an entirety of a top surface of the semiconductor stack 220 according to step 106 in FIG. 1. In some embodiments, the insulating layer 310 is made of a dielectric such as silicon dioxide (SiO₂) or silicon nitride (SiN). In some embodiments, the insulating layer 310 has a thickness ranging from about 2500 angstroms to about 3500 angstroms. The insulating layer 310 may be formed by, for example, plasma-enhanced chemical vapor deposition (PECVD).

Next, a photosensitive layer 320 is formed on the insulating layer 310 according to step 108 in FIG. 1. The photosensitive layer 320 can be applied on the insulating layer 310 by a spin-coating process. Subsequently, a soft-baking process may be performed to dry the photosensitive layer 320. The soft-baking process can remove solvent from the photosensitive layer 320, fully cover the insulating layer 310, and harden the photosensitive layer 320.

Next, a mask 330 is provided above the photosensitive layer 320. The mask 330 includes a plurality of transparent portions 332 and a plurality of opaque portions 334 that form a geometric pattern to be transferred onto the photosensitive layer 320. The transparent portions 332 and the opaque portions 334 may be alternately arranged. That is, adjacent transparent portions 332 are spaced apart by one of the opaque portions 334. The mask 330 may be a binary mask or a phase shift mask.

Subsequently, an exposure process is performed to expose the photosensitive layer 320 to actinic radiation 340 through the mask 330 according to step 110 in FIG. 1. During the exposure process, the transparent portions 332 of the mask 330 allow the actinic radiation 340 to irradiate the photosensitive layer 320, while the opaque portions 334 of the mask 330 prevent the actinic radiation 340 from irradiating the photosensitive layer 320, so that a duplicate of the geometric pattern appears in the photosensitive layer 320. After the exposure process is performed, the photosensitive layer 320 includes a plurality of exposed portions 322 that correspond to the transparent portions 332 of the mask 330 and a plurality of unexposed portions 324 that correspond to the opaque portions 334 of the mask 330.

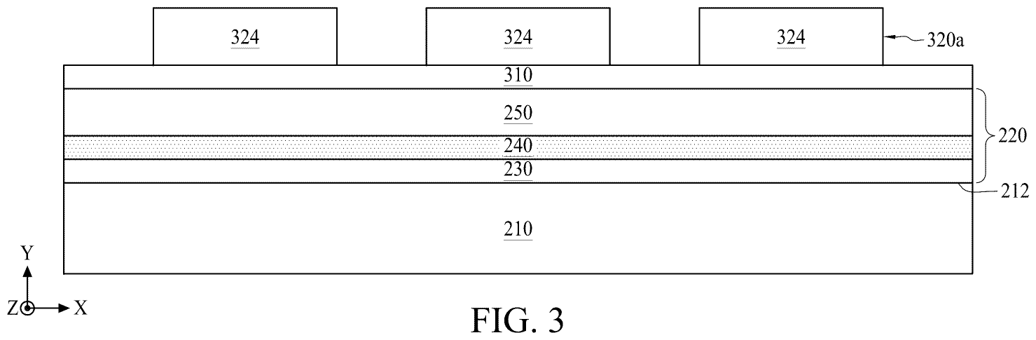

Referring to FIG. 3, a developing process is performed to remove the exposed portions 322 of the photosensitive layer 320 according to step 112 in FIG. 1. Specifically, the substrate 210 having the semiconductor stack 220 and the photosensitive layer 320 is immersed in a developer to preferentially remove the exposed portions 322, such that a target pattern 320a comprised of the unexposed portions 324 is formed. After the developing process is performed, portions of the insulating layer 310 are exposed through the target pattern 320a. The developer is a positive-tone developer that selectively dissolves and removes the exposed portions 322 of the photosensitive layer 320.

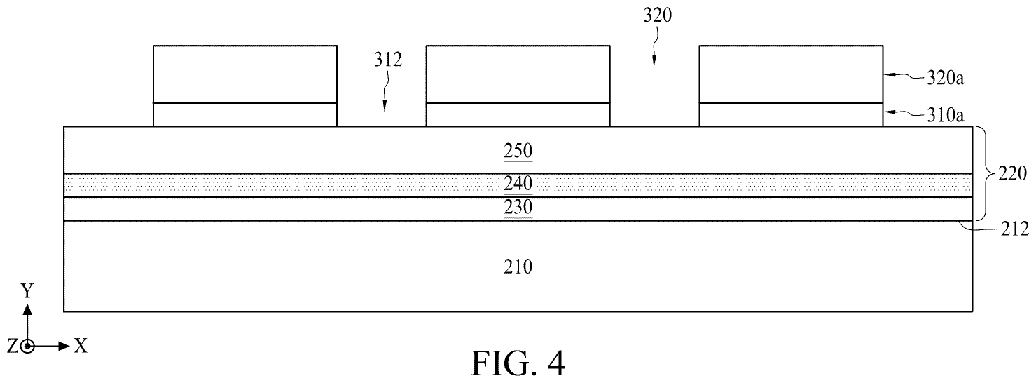

Referring to FIG. 4, a first etching operation is performed to etch the portions of the insulating layer 310 exposed through the target pattern 320a according to step 114 in FIG. 1. Accordingly, one or more openings 312 penetrating through the insulating layer 310 are formed, thereby forming a patterned mask layer 316. The patterned mask layer 316 is used as a hard mask for patterning of the underlying layers. In some embodiments, the insulating layer 310 is anisotropically dry-etched, using a reactive ion etching (RIE) process, for example, so that a width of spaces between the exposed portions 322 is maintained in the openings 312. After the openings 312 are formed, the patterned photoresist layer 320 is removed in an ashing and/or wet strip process, for example. The wet strip process may chemically alter the patterned photoresist layer 320 so that it no longer adheres to the patterned mask layer 316.

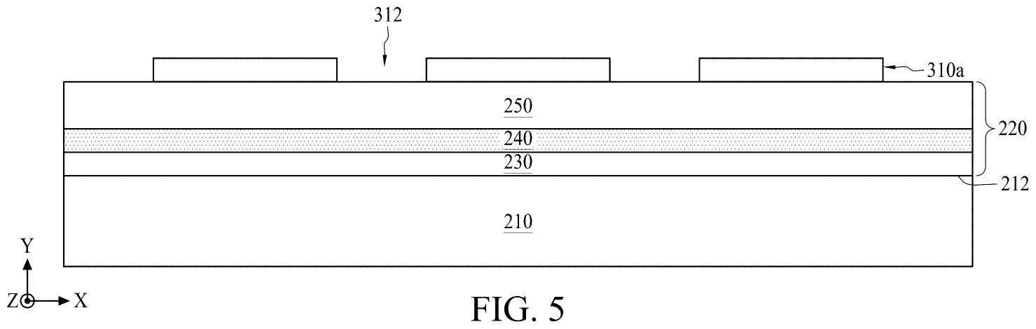

Subsequently, the structure including the semiconductor substrate 210, the semiconductor stack 220, and the patterned mask layer 316, as illustrated in FIG. 5, is loaded into an etching chamber. Next, the method 100 proceeds to step 116, in which a second etching operation is performed to etch the semiconductor stack 220, and hence form a plurality of mesa structures 222 as shown in FIGS. 6 and 7. The second etching operation is performed by supplying an etchant into the etching chamber to etch the semiconductor stack 220.

In some embodiments, portions of the second cladding layer 250, the active layer 240, and the first cladding layer 230 are removed during the second etching operation. The mesa structures 222 on the semiconductor substrate 210 include a patterned first cladding layer 232, a patterned active layer 242, and a patterned second cladding layer 252. As illustrated in FIG. 7, each mesa structure 222 tapers from the semiconductor substrate 210 toward the patterned second cladding layer 252. In addition, the mesa structure 222 may have an inclined surface 224 which has a substantially consistent inclination along the entire inclined surface 224.

During the second etching operation, the first cladding layer 230, the active layer 240, and the second cladding layer 250 are isotropically etched, using a wet etching process, for example. In wet etching the first cladding layer 230, the active layer 240, and the second cladding layer 250, an isotropic etch profile is produced, in which etching occurs at a same rate in all directions. More particularly, in the second etching operation, the semiconductor stack 220 is etched in a thickness direction (i.e., the Y-axis direction) and simultaneously in X- and Z-axis directions. As a result, the mesa structures 222 have an undercut shape relative to the patterned mask layer 316 in the X- and Z-axis directions. That is, at least part of the mesa structures 222 (in this embodiment, the entirety of the mesa structures 222) has a shape in which a width of the mesa structures 222 in the X-axis direction is less than a width of the patterned mask layer 316 in the X-axis direction. As a result, an overhang portion of the patterned mask layer 316 is formed relative to the mesa structures 222 in the X-axis direction.

The semiconductor stack 220 is etched using Br-based chemicals. In some embodiments, an additional reagent is added to the Br-based chemicals. For example, the second etching operation uses a wet etching solution having hydrogen bromide (HBr) and bromide (Br) in a ratio of about 1:17 to etch the semiconductor stack 220. In some embodiments, the reagent includes water. For example, the etchant includes about 30 ml of a mixture of bromide (Br) and hydrogen bromide (HBr), and about 80 ml of water. The second etching operation may be performed for a duration of about 70 seconds. The creation of mesa structures 222 with adequate critical dimension (CD) uniformity is a major challenge of the manufacturing process. The wet etching solution is used to manufacture the mesa structures 222 with an overall CD variation of less than 0.1 μm. For example, the width (in the X-axis direction and/or the Z-axis direction) of the mesa structure 222 deviates from a predetermined width by substantially less than 0.1 μm, and a height (in the Y-axis direction) of the mesa structure 222 deviates from a predetermined height by less than 0.1 μm.

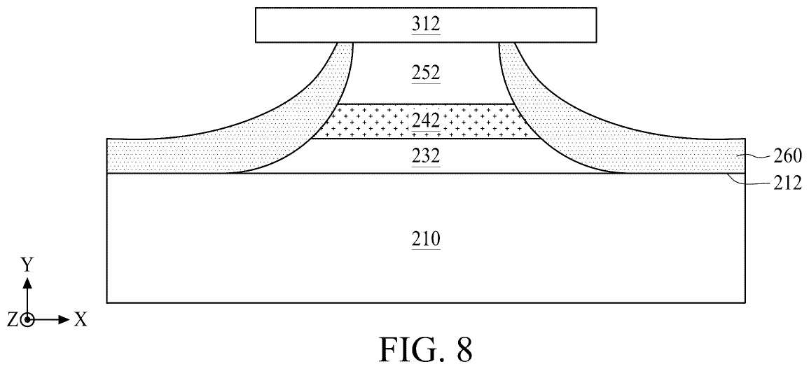

After the second etching operation is performed, the semiconductor substrate 210 on which the mesa structures 222 is formed is unloaded from the etching chamber and loaded into a reactor of, for example, an MOCVD system. Referring to FIG. 8, a first current-blocking layer 260 is grown around the mesa structures 222 according to step 118 in FIG. 1. In some embodiments, the first current-blocking layer 260 is grown on the inclined surfaces 224 of the mesa structures 222 and a portion of the front surface 212 of the semiconductor substrate 210 exposed through the mesa structures 222. The first current-blocking layer 260 may be a layer that has a topology following a topology of the exposed portion of the front surface 212 of the semiconductor substrate 210 and the inclined surfaces 224 of the mesa structures 222. The first current-blocking layer 260 is grown while leaving the patterned mask layer 316 on the mesa structures 222. The first current-blocking layer 260 is grown by, for example, MOCVD using the patterned mask layer 316 as a selective grow mask. The first current-blocking layer 260 includes a III-V group compound semiconductor, for example, InP. The first current-blocking layer 260 may be of the second conductivity type. In some embodiments, zinc (Zn) is added as a p-type dopant in the first current-blocking layer 260.

Before the formation of the first current-blocking layer 260, a cleaning operation may be performed to clean exposed surfaces of the mesa structures 222 and the semiconductor substrate 210.

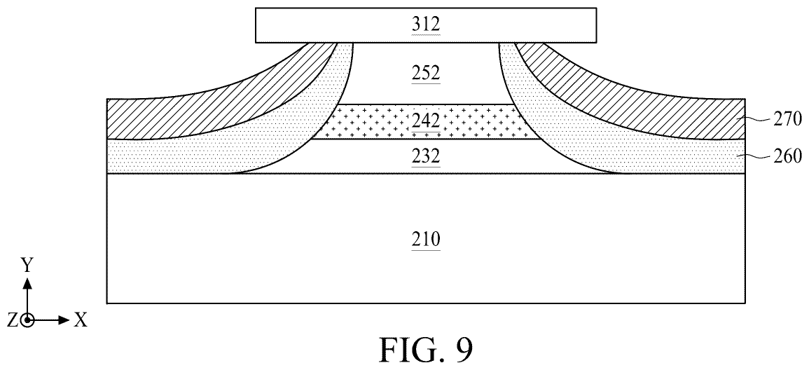

Referring to FIG. 9, a second current-blocking layer 270 is epitaxially grown on the first current-blocking layer 260 according to step 120 in FIG. 1. The second current-blocking layer 270 includes a III-V group compound semiconductor, for example, InP. The second current-blocking layer 270 may be of the first conductivity type.

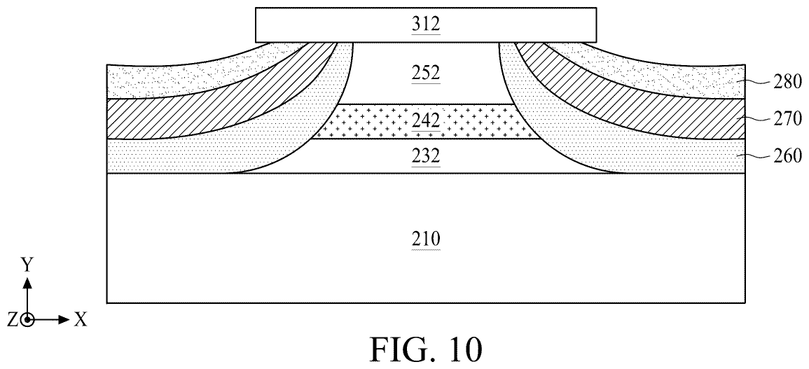

Referring to FIG. 10, a third current-blocking layer 280 is grown on the second current-blocking layer 270 according to step 122 in FIG. 1. The third current-blocking layer 260 includes a III-V group compound semiconductor, for example, InP. The third current-blocking layer 260 may be of the second conductivity type.

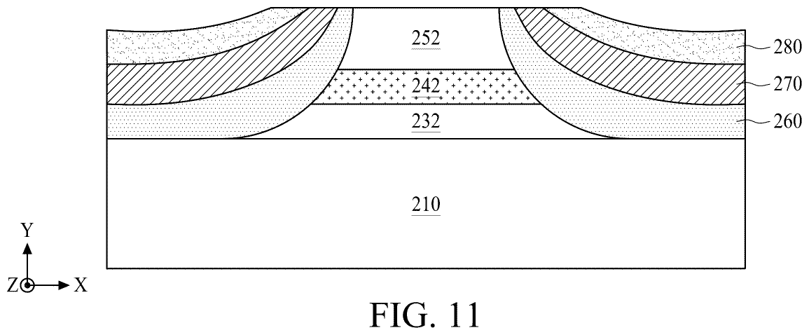

Referring to FIG. 11, the patterned mask layer 316 is removed from the patterned second cladding layer 252 and the first to third current-blocking layers 260 to 280 according to step 124 in FIG. 1. For example, in embodiments where the patterned mask layer 316 includes silicon dioxide, a wet etching can be performed using dilute hydrofluoric acid. In embodiments where the patterned mask layer 316 includes silicon nitride, a wet etching may be performed using dilute hydrofluoric acid or hot phosphoric acid.

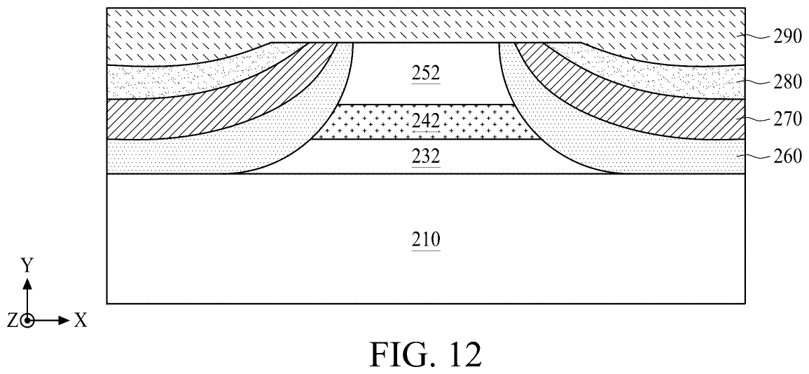

Referring to FIG. 12, a capping layer 290 is grown on the patterned second cladding layer 252 and the first to third current-blocking layers 260 to 280 according to step 126 in FIG. 1. The capping layer 290 has the second conductivity type. Consequently, the semiconductor optical device 20 is formed.

Some embodiments of the present disclosure provide a method of fabricating a semiconductor optical device, including providing a semiconductor substrate having a first conductivity type; depositing a first cladding layer having the first conductivity type on the semiconductor substrate; depositing an active layer on the first cladding layer; depositing a second cladding layer having a second conductivity type on the active layer, wherein the second conductivity type is different from the first conductivity type; forming a patterned mask layer over the second cladding layer; and performing an etching operation to sequentially remove portions of the second cladding layer, the active layer and the first cladding layer exposed through the patterned mask layer, thereby forming a mesa structure on the semiconductor substrate, wherein the etching operation uses an etchant comprising Br-based chemicals.

Some embodiments of the present disclosure provide a method of fabricating a semiconductor optical device, including loading a layer stack into an etching chamber, wherein the layer stack comprises a semiconductor substrate having a first conductivity type; a first cladding layer having the first conductivity type on the semiconductor substrate; an active layer on the first cladding layer; a second cladding layer having a second conductivity type on the active layer, wherein the second conductivity type is different from the first conductivity type; and a patterned mask layer on the second cladding layer. The method further includes supplying an etchant into the etching chamber to sequentially remove portions of the second cladding layer, the active layer and the first cladding layer exposed through the patterned mask layer to form an opening having a sidewall, wherein the entire sidewall has a substantially consistent gradient, and the etchant comprises bromine compounds.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor optical device, comprising:
providing a semiconductor substrate having a first conductivity type;
depositing an active layer over the semiconductor substrate;
depositing a first cladding layer having a second conductivity type on the active layer, wherein the second conductivity type is different from the first conductivity type;
forming a patterned mask layer over the first cladding layer; and
performing a first etching operation to remove portions of the first cladding layer and the active layer exposed through the patterned mask layer, thereby forming a mesa structure on the semiconductor substrate,
wherein the first etching operation uses an etchant comprising Br-based chemicals.

2. The method of claim 1, wherein the etchant comprises bromide (Br) and hydrogen bromide (HBr).

3. The method of claim 2, wherein the first etching operation is performed using bromide (Br) and hydrogen bromide (HBr) in a ratio of about 1:17.

4. The method of claim 3, wherein the etchant comprises about 30 ml of a mixture of bromide (Br) and hydrogen bromide (HBr), and about 80 ml of water.

5. The method of claim 1, wherein the first etching operation is performed for a duration of about 70 seconds.

6. The method of claim 1, further comprising:
depositing a first current-blocking layer having the second conductivity type around the mesa structure;
depositing a second current-blocking layer having the first conductivity type on the first current-blocking layer;
depositing a third current-blocking layer having the second conductivity type on the second current-blocking layer;
removing the patterned mask layer from the first cladding layer; and
depositing a capping layer having the second conductivity type over the mesa structure and the third current-blocking layer.

7. The method of claim 1, wherein a width of the mesa structure tapers from the semiconductor substrate toward the second cladding layer.

8. The method of claim 1, wherein the mesa structure comprises an inclined surface having a substantially consistent inclination along the entire inclined surface.

9. The method of claim 1, wherein the mesa structure comprises a curved surface having a substantially consistent curvature along the entire curved surface.

10. The method of claim 1, wherein the forming of the patterned mask layer comprises:
depositing an insulating layer on the first cladding layer;
forming a photoresist pattern on the insulating layer; and
performing a dry etching operation on portions of the insulating layer exposed through the photoresist pattern.

11. The method of claim 10, wherein the insulating layer has a thickness between about 2500 angstroms and about 3500 angstroms.

12. The method of claim 1, further comprising depositing a second cladding layer on the semiconductor substrate before the deposition of the active layer, wherein a portion of the second cladding layer not protected by the patterned mask layer is etched during the first etching operation.

13. The method of claim 12, wherein the semiconductor substrate, the first cladding layer, and the second cladding layer comprise indium phosphide (InP).

14. The method of claim 1, wherein a width of the mesa structure deviates from a predetermined width by substantially less than 0.1 μm, and a height of the mesa structure deviates from a predetermined height by less than 0.1 μm.

15. A method of fabricating a semiconductor optical device, comprising:
loading a layer stack into an etching chamber, wherein the layer stack comprises:
a semiconductor substrate having a first conductivity type;
an active layer over the semiconductor substrate;
a first cladding layer having a second conductivity type on the active layer, wherein the second conductivity type is different from the first conductivity type; and
a patterned mask layer on the first cladding layer;
supplying an etchant into the etching chamber to remove portions of the first cladding layer and the active layer exposed through the patterned mask layer to form an opening having a sidewall,
wherein the entire sidewall has a substantially consistent gradient, and the etchant comprises Br-based chemicals.

16. The method of claim 15, wherein the sidewall is a curve with increasing curvature from the semiconductor substrate toward the first cladding layer.

17. The method of claim 15, wherein the opening is formed by a wet etching operation.

18. The method of claim 17, wherein the wet etching operation is performed using the etchant comprising bromide (Br) and hydrogen bromide (HBr).

19. The method of claim 18, wherein the wet etching operation is performed using bromide (Br) and hydrogen bromide (HBr) in a ratio of about 1:17.

20. The method of claim 19, wherein the wet etching operation is performed using the etchant comprising about 30 ml of a mixture of bromide (Br) and hydrogen bromide (HBr), and about 80 ml of water.
